(19) United States
(12) Patent Application Publication
(10) Pub. No.: US 2008/0261155 A1
(43) Pub. Date: Oct. 23, 2008

(54) Metallic Air-Bridges

(75) Inventors: Tatiana Borzenko, Wurzburg (DE); Charles Gould, Wurzburg (DE); Georg Schmidt, Lindenflur (DE); Laurens W. Molenkamp, Wurzburg (DE)

Correspondence Address: BROWDY AND NEIMARK, P.L.L.C.;624 NINTH STREET, NW, SUITE 300, WASHINGTON, DC, 20001-5303, US

(73) Assignee: ETaCH AG, Schlieren (CH)

(21) Appl. No.: 11/579,652

(22) PCT Filed: May 6, 2005
(86) PCT No.: PCT/CH2005/000256

§ 371 Date: Nov. 6, 2006

(51) Int. Cl. G03F 7/00

(52) U.S. Cl. 430/311

(57) ABSTRACT

A lithographic method of producing an air-bridge (10) comprises the steps of providing a sequence of a bottom resist layer (2), a shield layer (3) and a top resist layer (4), removing the top resist layer (4) and subsequently the shield layer (3) in the area of the bridge span, removing the bottom resist layer (2) in the area of the pillars of the bridge, forming a metal layer (8) on the sequence of layers, and removing the resist layers (2, 4) together with shield layer portions (3) and metal-coated portions (9) to create the air-bridge.

In the production of electronic circuits, on whatever substrate, the crossing of wires is usually avoided by good circuit layout design. However, the increased complexity, and indeed effect, of many modern circuits, means that this is not always possible or desirable. Consequently wires cross, and although it is possible to allow wires to do so by being embedded within the different layers of the circuit, such a solution typically requires at least one second, insulating layer, where this layer is of solid form, being constructed between the two wires. The creation of such an intermediate layer is frequently undesired, complicated and costly.

In a different situation, or as an alternative solution to the same difficulty, the connection between parts of an electronic circuit where these may or may not be on the same substrate is achieved by wire bonding, that is, taking a pre-existing wire and using it to complete the electrical connection by bonding it to pads at its two ends. This is pragmatically limited by the dimensions of the wire, and thus of the pads, which can be conveniently physically handled, which dimensions are large (microns) compared to the track line-width of modern electronic circuits.

With recent advances in the study of electronic transport in sophisticated micro- and nanostructures, a demand has arisen for conductive air-bridge elements because of the continuing miniaturization of devices and the need to contact small objects located close together.

The present invention is that of a metallic air-bridge, which is formed in situ and which is capable of making an electrical connection between two parts of an electronic circuit, characterized in that it is only partially supported, including near its ends, and that for at least a significant part of its length it spans free space (where this significance lies in what it crosses rather than any ratio between the length of the bridge and the length of its span).

To briefly address the known prior art, various types of suspended microstructures have found application in micro- and nanodevices. For instance, G. J. Dolan and J. H. Dunsmuir, (Physica B 152 (1988) 7) describe sacrificial suspended bridges of polymethyl methacrylate (PMMA) used to fabricate tunnel junctions. In micro-electromechanical systems (MEMS), suspended structures are a standard functional element of many devices, e.g., cantilevers for atomic force microscopy (as described by, e.g., the Handbook of Microlithography, Micromachining, and Microfabrication. Volume 2: Micromachining and Microfabrication, edited by P. Rai-Choudhury, SPIE PRESS Monograph Vol. PM40, 1997, and by H.-M. Cheng, M. T. S. Ewe, G. T.-C. Chiu, and R. Bashir, J. Micromech. and Microeng. 11 (2001) 487). Suspended structures are also found in various types of air-gap resonators (M. Boucinha; P. Brogueira, V. Chu, and J. P. Conde, Appl. Phys. Lett. 77 (2000) 907), and in MEMS switches (K. E. Petersen, IBM J. Res. Dev. 23 (1979) 376, and C. Wang, R. Ramadoss, S. Lee, K. C. Gupta, V. M. Bright, and Y. C. Lee, Proc. 2001, ASME International Mechanical Engineering Congress and Exposition, New York 2001).

Considering the specific case of metallic structures, metallic air-bridges with sub-micrometer dimensions have been fabricated in the past. These have however all been fabricated using multilayer resist systems, where the characteristics of each layer are different. Such bridges are described in M. E. Sherwin, R. Corless, and J. R. Wendt, J. Vac. Sci. Technol. Bll (1993) 339: in M. E. Sherwin, J. A. Simmons, T. E. Eiles, N. E. Harff, and J. F. Klem, Appl. Phys. Lett. 65 (1994) 2326: in A. Yacoby, M. Heiblum, D. Mahalu, and H. Shtrikman, Phys. Rev. Lett. 74 (1995) 4047: and in M. Persson and J. Pettersson, J. Vac. Sci. Technol. B15 (1997) 1724. In all of these, a multilayer resist system (with resists of different characteristics) has been used, with a one-step electron beam exposure at a high acceleration voltage with dose variations between the pillars and the span (suspended area between the pillars) of the air-bridge followed by metal evaporation and lift-off. These studies employed three layer resist systems consisting of a bottom layer with low sensitivity (e.g., PMMA 950K) and a middle layer (e.g., a copolymer of polymethylmethacrylate with monomers of methacrylic acid (PMMA-MAA, 33%)) with highest sensitivity to electron exposure. The top layer (e.g., PMMA 200K) is less sensitive to electrons than the middle one in order to produce a negative profile suitable for the lift-off process. Due to the large difference in sensitivity between PMMA 950K and the PMMA-MAA 33%, combined with the smaller dose applied for the span than for the pillars, the resist development in the span area stops at the boundary between the layers. The correct choice of the dose used for the span is the critical point in the three-layer resist fabrication scheme, and is far from trivial because of the influence of backscattered electrons to the exposure of the span area. The backscattering is both substrate and voltage dependent.

As an added complication for using this route, uneven substrate surfaces represent an additional obstacle because the resist thickness is no longer constant and at different positions on the sample a recalibration of the process parameters may be necessary. In a previous publication (T. Borzenko, F. Lehmann, G. Schmidt, and L. W. Molenkamp, Microelectron. Eng. 67-68 (2003) 720) the present authors themselves presented metallic air-bridges fabricated on non-planar surfaces using a modified version of the three-layer resist scheme. The multilayer approach, however, remains complicated and requires calibration experiments for any new substrates.

There is thus a need for a simple process to make such air-bridges, such as is described in the present invention.

It is an object of the invention to provide a method to produce air bridge crossover structures.

The invention will now be described by the following description of embodiments according to the invention, with reference to the drawing, in which:

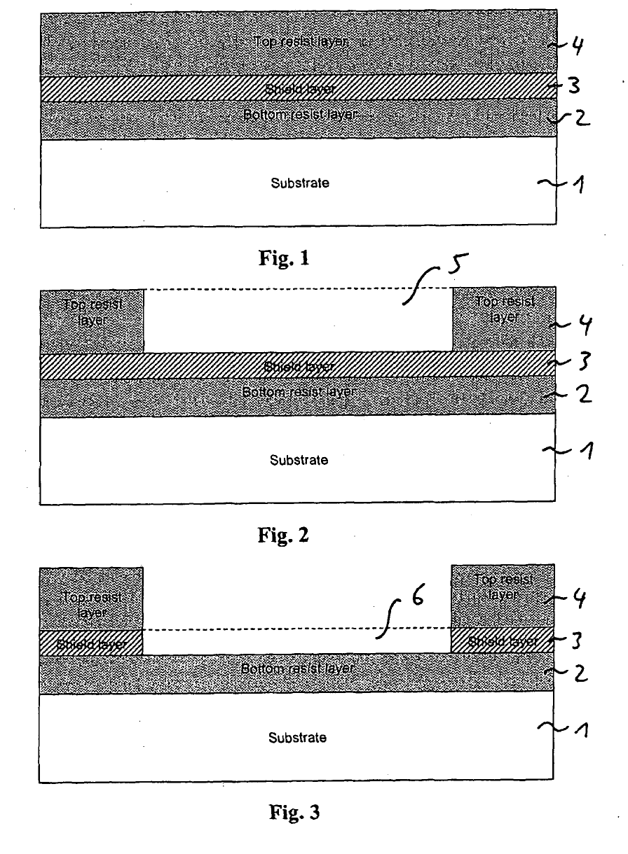

FIG. 1 to 6 show different steps of the optical lithography process to provide an air-bridge on a substrate according to a first embodiment of the invention.

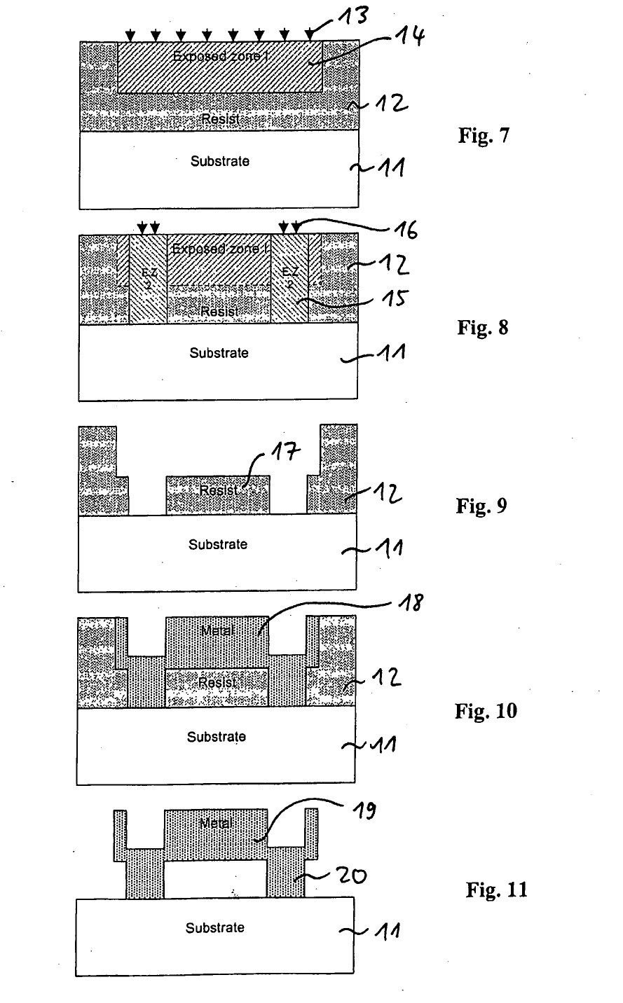

FIG. 7 to 11 show different steps of the electron beam lithography process to provide an air-bridge on a substrate according to a second embodiment of the invention.

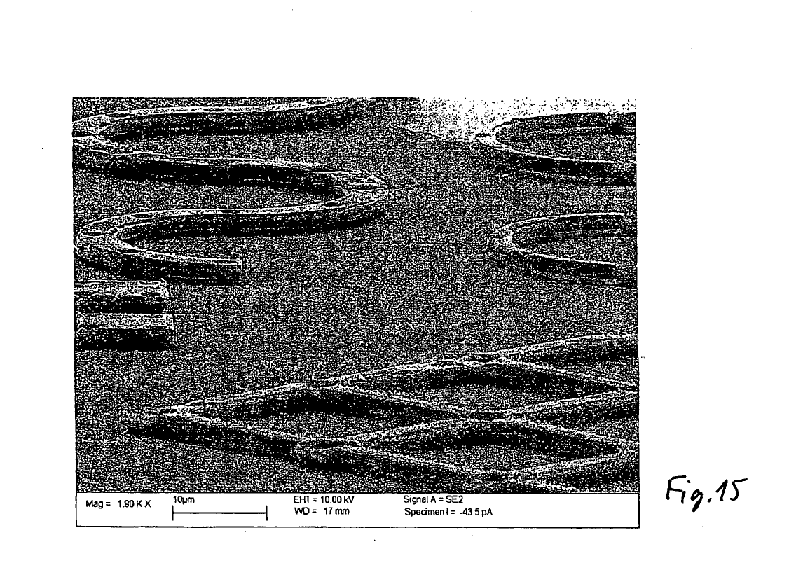

FIG. 12 shows a single air-bridge,

FIG. 13 shows air-bridges of different lengths,

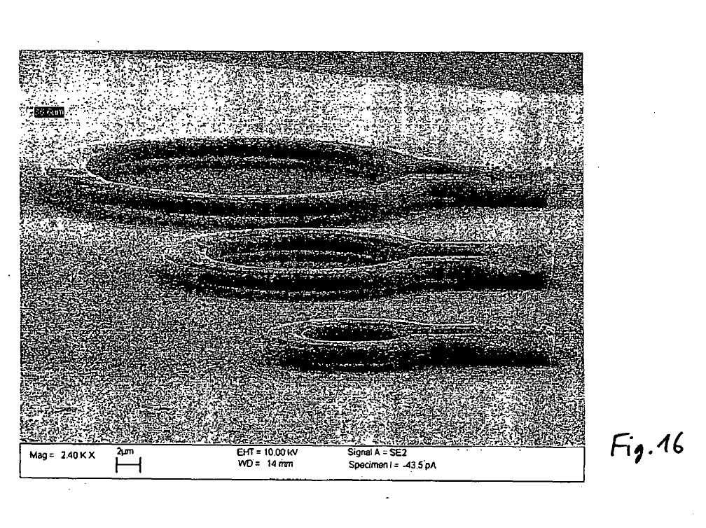

FIG. 14 shows a close-up of FIG. 13,

FIG. 15 shows S-curves and lattices,

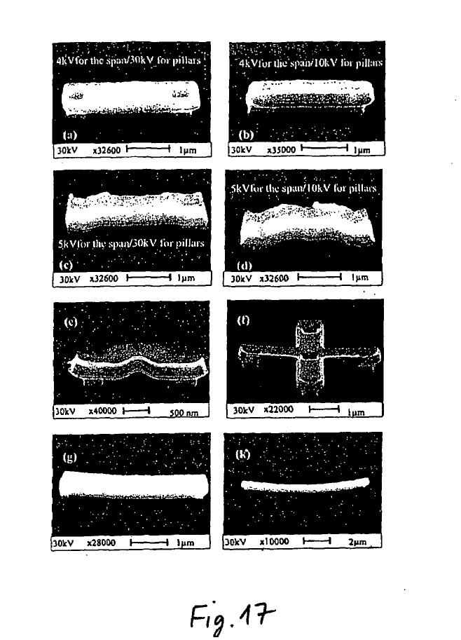

FIG. 16 shows suspended loops, and

FIG. 17 shows some examples of air-bridges; a, b, c, d show air-bridges fabricated using an identical layout for the e-beam exposure but with variation of the acceleration voltages for the span and the pillars; e shows an air-bridge fabricated using three different voltages: 30 kV for the pillars, 4 kV for the periphery of the span and 3 kV for the central part of the bridge; f shows a cross-shaped bridge; g is a Ti/Au (10/300 nm) bridge of 4 um, the longest span that is reproducibly stable; and k: a 10 um long air-bridge with one post torn off from the substrate.

FIG. 1 to 6 can be summarized showing schematic of the air-bridge fabrication technique using the shield layer. (1) layer assembly; (2) exposure and removal of the top resist layer; (3) removal of the shield layer; (4) exposure and removal of the bridge supports in the bottom resist layer; (5) metal evaporation and (6) resist liftoff resulting in the air-bridge

FIG. 7 to 11 can be summarized showing schematic of the air-bridge fabrication technique using different voltage exposure for the span and pillars. (7) exposure of the bridge span with low energy electrons (3-6 keV); (8) exposure of the bridge posts with high energy electrons (10-30 keV); (9) after development for 2 min in MIBK:IPA (1:5); (10) metal evaporation and (11) resist liftoff resulting in the air-bridge.

Bridges according to the present invention can be made by various techniques. Such bridges can be made e.g., optical lithography, e.g., by the following process which refer to FIG. 1-6:

On the substrate 1 a resist 2 for optical lithography is deposited, termed the bottom resist layer 2, with a thickness T1. On top of this resist layer a thin layer of a material A (shield layer 3) is deposited with a thickness T2. This material A has to be sufficiently opaque for the light which can be used to expose the bottom resist layer 2 to prevent such light from reaching and affected the bottom resist layer 2. On top of this layer A (3), a second layer 4 of optically sensitive resist is deposited (top resist layer 4) with a thickness T3. (resulting structure is shown in FIG. 1).

Importantly the second layer of resist 4 may be, and preferentially is, of the same material and sensitivity as the bottom resist layer 2, in contrast to the known prior art. The image of the part 5 of the bridge which is to be the ‘suspended’ part is then exposed into the top resist layer 4. During this process the shield layer 3 prevents the exposure of the bottom resist layer 2. The top resist layer 4 is then developed (FIG. 2) and the exposed resist removed. After development the shield layer 3 is removed 6 by any kind of suitable etching process (dry or wet etching) which leaves the bottom resist layer 2 unaffected (FIG. 3).

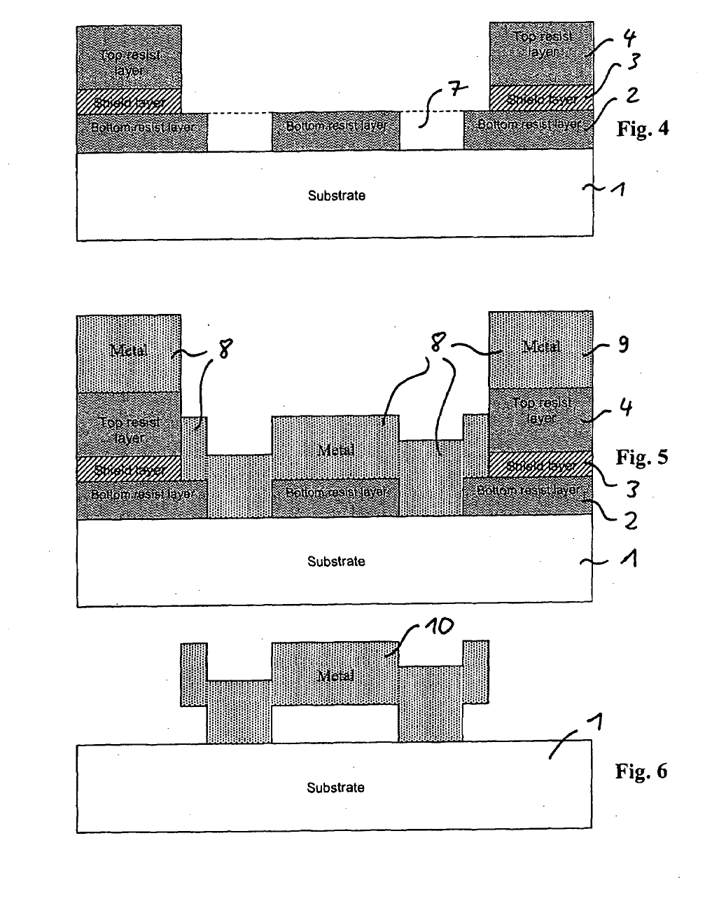

In a second optical lithography process the bottom resist layer 2 is exposed at the places 7 where the pillars of the bridges are placed. This process is so arranged (by mask design) as to leave unaffected the unexposed resist in the top resist layer 4. The resist is then developed and the exposed resist 7 removed (FIG. 4).

After development a metal layer 8 is evaporated (FIG. 5). The thickness of the metal layer is critically chosen to be larger than T1, to ensure connectivity between the bridge and the supports, and sufficiently smaller than T2+T3, to guarantee successful lift-off of the unwanted metal-coated portions 9 formed on the top of the upper resist 4. After the lift-off process the bridges 10 remain on the substrate (FIG. 6).

Examples of bridges made in such manner are shown in FIG. 12 to 14.

Bridges according to the present invention can also be made e.g., electron-beam lithography, e.g., by the following process according to a second embodiment according to the invention, shown in FIG. 7 to 11. In overview, this new method of fabricating metallic air-bridge microstructures is based on a single layer resist 12 and a variation of the electron energy used during the electron beam lithography process. Electrons in the range of 3-30 keV cause radiation-induced reactions in the resists to depths adjustable from fractions of a micrometer up to several micrometers. By varying the energy at which the lithography process is carried out, we obtain three-dimensional profiles in the electron beam resist after exposure and development. Air-bridge structures can then be created by metal evaporation and lift-off.

In detail, we present a reliable and fairly straightforward way to fabricate metallic air-bridges on any kind of substrate 11, and independent of surface morphology. We use electrons of different energies to create versatile air-bridge-like constructions. The method is based on the fact that electrons of different energies have a different penetration depth into e-beam resists, in particular, into PMMA. Although suspended structures fabricated in negative tone resists by variation of the electron energy during the lithography process were previously demonstrated, these structures were non-conductive and could not serve as contacts (see e.g., V. A. Kudryashov, T. Borzenko, V. Krasnov, and V. Aristov, Microelectron. Eng. 23 (1994) 307: V. A. Kudryashov, V. V. Krasnov, S. E. Huq, P. D. Prewett, and T. J. Hall, Microelectron. Eng. 30 (1996) 305: and D. M. Tanenbaum, A. Olkhovets, and L. Secaric, J. Vac. Sci. Technol. B19 (1997) 2829).

In our scheme, the area of the suspended structure can be exposed in a thick resist 12 using low energy electrons 13 (FIG. 7).

The acceleration voltage has to be chosen such that the penetration depth of the electrons is less than the resist thickness and create an “exposed zone 1” or 14.

We then expose small areas 15 (called EZ2 for “exposed zone 2”) using high energy electrons 16 (FIG. 8), which after development will appear as holes going down to the substrate l, while the suspended structure will only result in a trench 17 in the resist (FIG. 9).

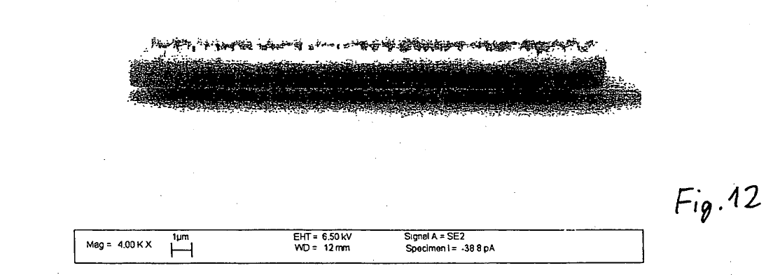

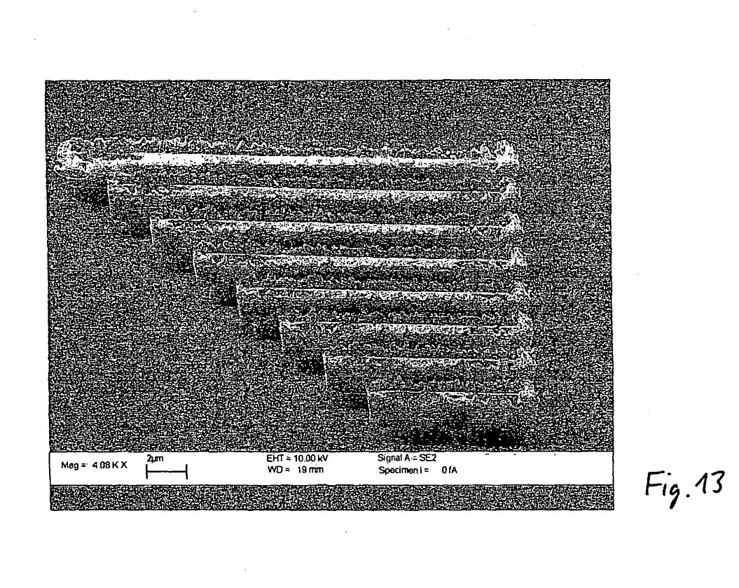

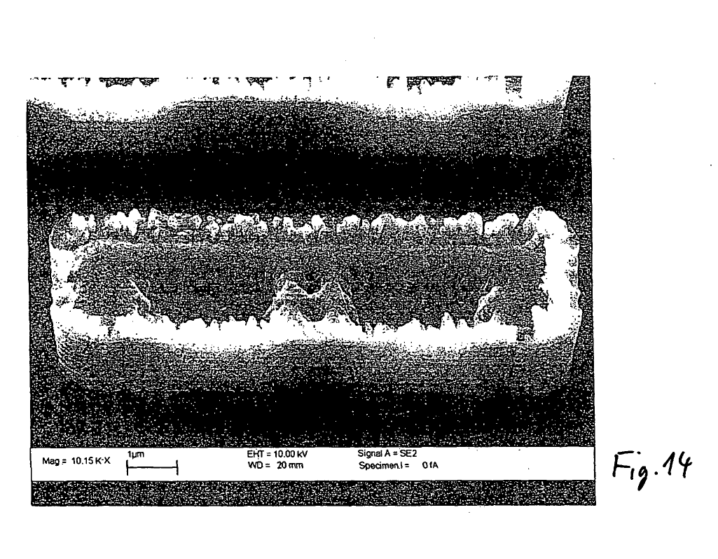

After metal evaporation (FIG. 10) creating the structure 18 and lift-off (FIG. 11) of the resist we obtain a free standing metallic structure 19 supported by posts 20 at the areas of high voltage exposure.

In a preliminary series of experiments, we measured the effective penetration depth of electrons at several acceleration voltages. For these experiments, silicon substrates were covered with PMMA layers of various thicknesses (750 nm-3 Em). PMMA 950K (4%) and PMMA 600K (7%) solutions in ethyl lactate were both investigated. For thicker layers, (>1 Em), more than one coating is necessary to reach the desired thickness. In case of multiple coating, the layer is baked for 5 min at 200° C. before each sub-sequent coating step. Because ethyl lactate is a weak solvent for PMMA, the previously deposited layer is practically not dissolved during the subsequent layer spin-coating. After the necessary thickness is reached, the sample is baked at 200° C. for one hour.

Our lithography system is a LEO 1525 scanning electron microscope, equipped with a thermal field emission electron gun, and connected to an ELPHY PLUS pattern generator. In a first experiment, we exposed 10×80 Em² rectangular areas in a 2.8 Em thick PMMA 950K film with doses varying from 20 to 1000 EC/cm². The samples were then developed in a mixture of methyl isobuthyl ketone (MIBK) and isopropylic alcohol (IPA) (1:5) for 2 minutes. The depth of the developed patterns was determined with an Alphastep profilometer. The results of the measurements that 3 keV electrons penetrate no deeper than 320 nm into PMMA, and 4 keV electrons are limited to 500 nm whereas 5 keV and 6 keV electrons can penetrate as deep as 650 nm and 850 nm, respectively. At high doses, the effective penetration depth decreases. This is probably caused by the onset of cross-linking in the PMMA film at very high electron exposure doses.

A second set of experiments was done on PMMA layers covered with a thin Au film (30 nm). This layer is necessary when PMMA films with a thickness of more than ˜1 Em are used in combination with acceleration voltages >˜7 keV. Such thick layers are needed to planarize surface relief before bridge fabrication; e.g. 600-700 nm high steps can be planarized with a ˜3 μm thick PMMA film. For acceleration voltages higher than ˜7 kV we have observed charging effects leading to defects in a thick resist. The charging vanishes when a thin surface metallization is applied. The Au film is thermally evaporated prior to electron exposure, and after the exposure it is removed in a I2+KI+H2O solution (ref: M. Köhler, “Ätzverfahren für die Mikrotechnik”, Wiley-VCH, 1998) for 10 seconds. Subsequently, the resist film is developed as described above. The effective penetration depth vs. electron energy was also determined for acceleration voltages between 3 and 12 and 12 kV. It is evident that with the Au film in place, the electrons penetrate slightly less deeply for a similar exposure dose. The effective penetration depth of 3-12 keV electrons was measured for 100, 300 and 500 EC/cm² exposure doses. The dose of 500 EC/cm² is close to the saturation regime, i.e., a further increase of the exposure dose and/or development time does not significantly influence the effective penetration depth for this range of voltages. In the saturation regime, 3 keV electrons produce changes in resist down to a depth of 250 nm; at 7 kV the exposure reaches 1 Em and at 12 kV the penetration depth is as large as 2.7 Em.

Based on the electron penetration depth data, we developed a process for the fabrication of air-bridges. As described above we exposed various structures at voltages between 3 and 6 kV, for which the penetration depth of the electrons is less than the resist thickness. The supporting posts of the structures were exposed at voltages between 10 kV and 30 kV. As above, the development was done using a mixture of MIBK:IPA (1:5) for 2 minutes. After development, a film of Ti (10 nm)/Au (300 nm) was evaporated followed by lift-off in acetone. In FIG. 15 (ADD), we show some examples of air-bridge structures fabricated using the method described above. For these structures we used different exposure parameters, which all lead to stable bridges. However, the structures exhibit markedly different profiles. The bridges shown in FIGS. 17 (a, b, c, and d) were fabricated by e-beam writing in a 750 nm thick PMMA layer using the same layout for the exposed pattern. The bridges have nominally the same dimensions, and the difference in shape is the result only of the difference in acceleration voltage. For example, 5 keV electrons used for the span of FIG. 17 (c and d) penetrate deeper into the resist; as a result the span is lower than in FIG. 17 (a and b) where the span was exposed at 4 kV. For the posts, 10 keV electrons (b and d) give wider posts than 30 keV (a and c) because of the stronger proximity effect. For fabrication of the bridge shown in e, three different voltages were used: 30 kV for the posts, 4 kV for the span, except for its central part, which was exposed at 3 kV. After Ti (300 nm) evaporation and lift-off we obtained a bridge whose central part rises above its periphery.

The air-bridges can have many different topologies, including crosses, lattices, curves etc. Please see the included FIGS. 15 and 16. However, there are some restrictions. The air-bridges described above have a thickness of only a few hundred nanometers and cannot be very long. For example, gold air-bridges with a thickness of 300-320 nm are stable up to a length of 3-4 um. For longer bridges, stresses in the metal start to compete with adhesion forces between the base of the pillars and the substrate. The span bends and eventually the bridge is destroyed. There is, however, a way around this limitation. Arbitrarily long conductive air-bridges can be fabricated when supported by appropriately spaced non-conductive pillars. The idea is based on the property of PMMA to reverse its tone from a positive resist to a negative one as a function of exposure dose. With increasing irradiation dose, cross-linking between polymer fragments starts to dominate over bond-breaking (scissions of main polymer chains), thereby transforming the PMMA into a three-dimensional high molecular weight network which is insoluble in most solvents. The electron dose necessary to transform spun-on PMMA into this insoluble high molecular weight substance depends on the resist thickness, the original molecular weight, the acceleration voltage, and the substrate. Detailed results of a study of PMMA behavior at higher electron irradiation doses and its subsequent applications have been done to support this invention (details will be added). Here we simply apply this property of PMMA to fabricate supporting pillars for long bridges.

After exposing and developing the end pillars and the long span as described previously, an additional exposure step is used to pattern the supplementary support posts with a dose of 20 mC/cm2. No development is performed after this step. Subsequently, metal (Ti (10 nm)/Au (300 nm)) is evaporated and lift-off is carried out. The cross-linked PMMA does not lift-off and supports the bridge. A part of a long meandering bridge with supporting pillars is shown in FIG. 15. This method allows for extended free standing metal structures with very few limitations to shape, which can be part of active devices.

In summary for the electron beam lithography process, we have shown how using a single layer resist and various acceleration voltages during electron beam lithography, one can fabricate versatile air-bridge constructions. The geometry is defined in the resist by using electrons of different penetration depth. Taking advantage of the property of PMMA to cross-link at high electron doses allows us to fabricate air-bridges of unlimited length supported by non-conductive pillars. The process is highly reliable because of the limited accuracy of the exposure dose needed to obtain good results. The process should also prove very useful for other applications in three-dimensional lithography where the well defined dependence of penetration depth on acceleration voltages should enable one to fabricate complex structures with superb flexibility.

The pragmatic nature of this approach can be seen in the included illustrations of such metallic air-bridges (see FIG. 12 to 17). As can be seen, the bridges can be made of significant length, where the span is many times the width of the bridge.

This technique can also be used to make various other structures which are sited mainly above the substrate surface. For instance, crosses, lattice structures or S-structures can be made supported at widely spaced points (see FIG. 15), or ring or split-ring structures supported only at the side can be made (see FIG. 16).

1. A lithographic method of producing an air-bridge (10) comprising the steps of
providing a resist (2, 4; 12) comprising one or more resist layers,
removing a first depth of the resist in the area (5; 14) of the bridge span,
removing a second depth of the resist in the area (7; 14) of the pillars of the bridge,
forming a metal layer (8) in the area (14) of the bridge span (14), and
removing the resist layers (2, 4) together with unwanted layer portions (3, 9; 12) to create the air-bridge (10; 19).

2. A lithographic method of producing an air-bridge (10) comprising the steps of
providing a sequence of a bottom resist layer (2), a shield layer (3) and a top resist layer (4),
removing the top resist layer (4) in the area (5) of the bridge span,
removing the shield layer (3) in the area (6) of the bridge span,
removing the bottom resist layer (2) in the area (7) of the pillars of the bridge,
forming a metal layer (8) on the sequence of layers, and
removing the resist layers (2, 4) together with shield layer portions (3) and metal-coated portions (9) to create the air-bridge (10).

3. The method according to claim 2, wherein the bottom resist layer (2) and the top resist layer (4) are different in type and/or thickness.

4. The method according to claim 2 or 3, wherein the thickness of the metal layer (8) is larger than the thickness of the bottom resist layer (2), to ensure connectivity between the bridge and the supports, and sufficiently smaller than the combined thickness of the shield layer (3) and the top resist layer (4), to guarantee successful lift-off of the unwanted metal-coated portions (9) formed on the top of the upper resist layer (4).

5. A lithographic method of producing an air-bridge (19) comprising the steps of
providing a resist layer (12),
removing a first depth of the resist layer (12) in the area (14) of the bridge span,
removing a second depth of the resist layer (12) in the area (15) of the pillars within the area (14) of the bridge span,
forming a metal layer (8) in the area (14) of the bridge span (14), and
removing the resist layer (12) to create the air-bridge (19).

6. The method according to one of claims 1 to 5, characterized in that these processes use optical lithography or electron beam lithography.

7. The method according to one of claims 1 to 6, characterized in that the metallic bridges formed are electronic circuit elements, capable of carrying electrical currents.

8. An electronic circuit element formed by a method according to one of claims 1 to 7.

9. The electronic circuit element according to claim 8, characterized in that it is intermittently supported by insulating supports formed at the same time as the circuit element.

10. The electronic circuit element according to claim 8 or claim 9, characterized in that said element is a linear bridge, a single or multiple bridge junction, such as a cross, a lattice, a suspended ring or a split-ring structure of circular or other geometry.
